(19) United States
(12) Patent Application Publication
(10) Pub. No.: US 2026/0303047 A1
(43) Pub. Date: Oct. 1, 2026

(54) MICROPHONES WITH SIGNAL-TO-NOISE RATIO ON-DEMAND

(71) Applicant: Infineon Technologies AG, Neubiberg (DE)

(72) Inventors: Jose Luis Ceballos, Villach (AT); Andreas Wiesbauer, Pörtschach a. W. (AT); Fulvio Ciciotti, Bad Bleiberg (AT); Christopher Igor Rogi, Villach (AT)

(21) Appl. No.: 19/091,078

(22) Filed: Mar. 26, 2025

(51) Int. Cl. H03G 3/30; H03G 3/00; H04R 3/00; H04R 29/00

(52) U.S. Cl. CPC H03G 3/3015; H03G 3/001; H03G 3/008; H04R 3/00; H04R 29/004

(57) ABSTRACT

A circuit includes a programmable gain amplifier to receive an analog input signal; an integrator having an input coupled to an output of the programmable gain amplifier; and a gain change component to monitor the analog input signal, and to change a gain of the programmable gain amplifier and a gain of the integrator based on the monitored analog input signal, wherein a gain change of the programmable gain amplifier is inversely related to a gain change of the integrator.

### TECHNICAL FIELD

The present invention relates generally to microphones with signal-to-noise ratio (SNR) on-demand and to a corresponding method.

### BACKGROUND

State-of-the-art microphone systems provide a high SNR using a programmable gain amplifier (PGA) cascaded with a Sigma-Delta Analog-to-Digital Converter (SD ADC). The signal path of the microphone system should ideally have high performance (including both high SNR and also high dynamic range) but with low power. Some solutions can provide high SNR but make the ADC operate in a multibit mode or consume additional power. Other solutions trade off SNR and dynamic range.

### SUMMARY

According to an embodiment, a circuit comprises a programmable gain amplifier configured to receive an analog input signal; an integrator having an input coupled to an output of the programmable gain amplifier; and a gain change component configured to monitor the analog input signal, and configured to change a gain of the programmable gain amplifier and a gain of the integrator based on the monitored analog input signal, wherein a gain change of the programmable gain amplifier is inversely related to a gain change of the integrator.

According to an embodiment, a method comprises receiving an analog input signal at an input of a programmable gain amplifier and amplifying, by the programmable gain amplifier, analog signal to form an amplified signal; integrating, by an integrator having an input coupled to an output of the programmable gain amplifier, the amplified signal; monitoring the analog input signal; and changing a gain of the programmable gain amplifier and a gain of the integrator based on the monitored analog input signal, wherein a gain change of the programmable gain amplifier is inversely related to a gain change of the integrator.

According to an embodiment, a circuit comprises a circuit input for receiving an analog signal; a first amplifier having an input coupled to the circuit input; a second amplifier having an input coupled to an output of the first amplifier; an analog-to-digital converter (ADC) having an input coupled to an output of the second amplifier and output coupled to a circuit output; and a gain change component configured for monitoring the analog signal, the gain change component coupled to a gain change input of the second amplifier, and to a gain change input of an integrator in the ADC, wherein a gain change of the second amplifier is inversely related to a gain change of the integrator.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic diagram of a circuit including a programmable gain amplifier (PGA) and a sigma-delta analog-to-digital converter (ADC), as well as gain adjustment features according to an embodiment;

FIG. 1B is a schematic diagram of an exemplary chopper circuit for use in the circuit of FIG. 1A;

FIG. 2 is a schematic diagram of a circuit including a PGA and an integrator, as well as gain adjustment features according to an implementation of the embodiment of FIG. 1A;

FIG. 3 is a plot of the gain characteristics of the circuit of FIG. 2 in various gain modes, according to the implementation of FIG. 2;

FIG. 4 is a schematic diagram of a circuit including a PGA and an ADC, as well as gain adjustment features according to an implementation of the embodiment of FIG. 1A;

FIG. 5 is a schematic diagram of a circuit including a PGA and an integrator, according to an implementation of the embodiment of FIG. 1A;

FIG. 6A is a plot of PGA capacitor array values and ADC capacitor array values according to an embodiment;

FIG. 6B is a plot of PGA gain array values, according to an embodiment;

FIG. 7 is a plot of the ADC input signal and a source follower output signal, according to an embodiment; and

FIG. 8 is a plot of the “A-Weighted” Signal-to-Quantization-Noise Ratio (SQNR) versus input audio frequency and amplitude using Monte Carlo (MC) analysis.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

According to an embodiment, a microphone circuit receives an analog input signal from, for example, a microelectromechanical system (MEMS) device, processes and converts the analog input signal and provides a digital output signal. The microphone circuit includes a programmable gain amplifier (PGA) and an analog-to-digital converter (ADC). A gain change component monitors the magnitude of the analog input signal and reduces (or increases) the gain of the PGA synchronously with an increment (or decrement) of an integrator gain in the ADC. It will be understood by those skilled in the art that monitoring the analog input signal can be accomplished by the actual analog input signal itself or a later processed version of the analog input signal at an internal node or output node of the microphone circuit. The ADC comprises a sigma-delta ADC (SD ADC) including an integrator in an embodiment. In some embodiments the integrator is a switched capacitor circuit, wherein the input capacitors are switched but the feedback loop is not switched and so any stability issues are diminished. The dynamic range of the microphone circuit can be extended at the same time as the SNR is increased, at least in part because the PGA does not saturate.

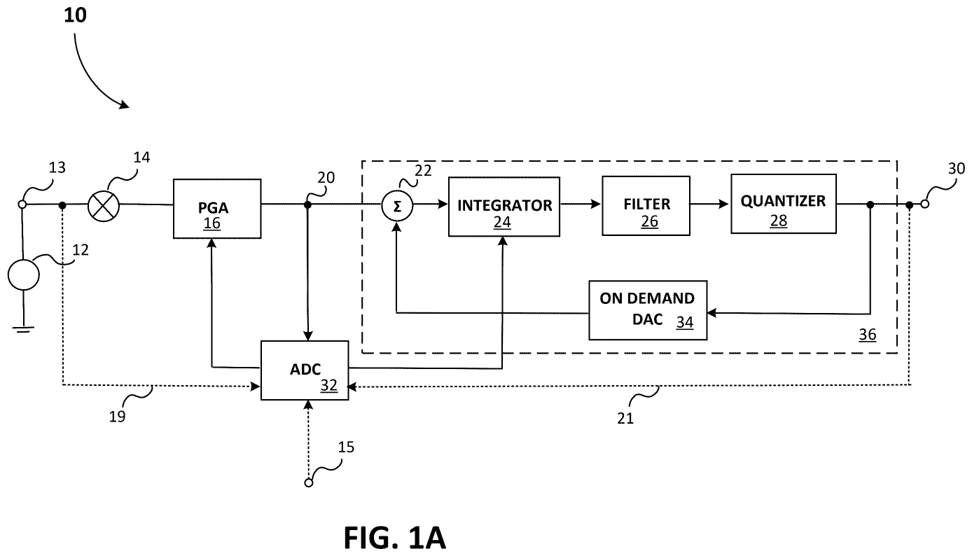

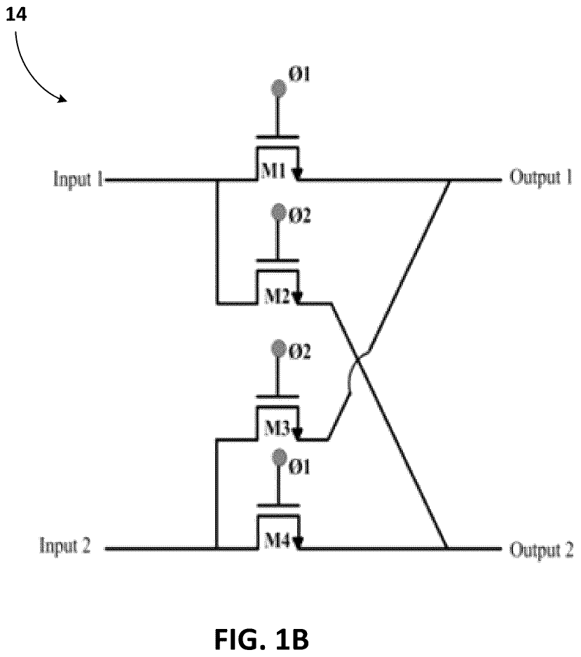

FIG. 1A is a schematic diagram of a microphone circuit 10 including an analog input voltage source 12 coupled to a system input node 13, according to a first embodiment. The analog input voltage source 12 can be a buffered microelectromechanical system (MEMS) device, such as a buffered integrated circuit capacitive membrane MEMS device in an embodiment. Microphone circuit 10 comprises a chopper 14 having an input coupled to the system input node 13, and a PGA 16 having an input coupled to the output of chopper 14. PGA 16 can be an analog amplifier with at least one adjustable feedback resistor, or a switched capacitor amplifier with a set of selectable feedback capacitors. The output of PGA 16 is coupled to node 20. Microphone circuit 10 also comprises a sigma-delta ADC (SD ADC) 36 including a summer 22, integrator 24, filter 26, quantizer 28, and an on-demand digital-to-analog converter (DAC) 34. In an embodiment, summer 22 comprises a circuit node or an actual summer component, integrator 24 comprises a fixed feedback capacitor and a set of selectable input capacitors. Filter 26 comprises a low pass filter, and quantizer 28 comprises a multibit quantizer. On-demand DAC 34 has an input coupled to digital output node 30, and an input coupled to an input node of summer 22. The on-demand DAC 34 has a set of selectable capacitors that are explained in further detail below. Finally, ADC 32 has an input node coupled to node 20, or for otherwise sensing the analog input voltage (for example at system input node 13, digital output node 30, or any other internal node of microphone circuit 10). ADC 32 outputs gain control signals to a control input of PGA 16, and gain control signals to a control input of integrator 24.

While a direct connection is shown in FIG. 1A between node 20 and the input of ADC 32, in some embodiments the ADC 32 can also be controlled from system input node 13 (if a low impedance source is available-in order to avoid noticeable “kickback” artifacts) through path 19. ADC 32 can also be controlled by the digital output node 30 through path 21, or externally at node 15. In some embodiments, ADC 32 can comprise a flash ADC, a comparator, or other digital circuit.

In operation, microphone circuit 10 dynamically adjusts its gain settings based on the amplitude of the signal at system input node 13. For small input signals, ADC 32 detects the low amplitude and configures the PGA 16 with high gain settings while simultaneously configuring the integrator 24 with reduced input capacitance. This complementary adjustment increases the SNR for small signals where noise performance is more important, without saturating subsequent stages. Conversely, for large input signals, ADC 32 reconfigures the PGA 16 with lower gain settings while increasing the input capacitance of integrator 24. This adjustment prevents saturation of the PGA 16 while maintaining adequate SNR for large signals where the signal level already provides sufficient separation from the noise floor. The synchronous and inversely proportional gain adjustments between the PGA 16 and integrator 24 ensure that the overall transfer function remains consistent, avoiding discontinuities in the signal path that would otherwise introduce distortion. In various embodiments, chopper 14 compensates for the DC offset of PGA 16 as explained in embodiments below.

Chopper 14 is shown at the schematic level in FIG. 1B comprising transistors M1, M2, M3, and M4 for alternatingly reversing the polarity of the input signal. The current path of transistor M1 is coupled between Input 1 and Output 1, the current path of transistor M2 is coupled between Input 1 and Output 2, the current path of transistor M3 is coupled between Input 2 and Output 1, and the current path of transistor M4 is coupled between Input 2 and Output 2. The gates of transistors M1 and M4 are controlled by a phase 01 control signal, and the gates of transistors M2 and M3 are controlled by a phase 02 control signal. In an embodiment, the phase signals can be non-overlapping clock signals that 180° out of phase. The operation of chopper 14 in other embodiments is described in greater detail below.

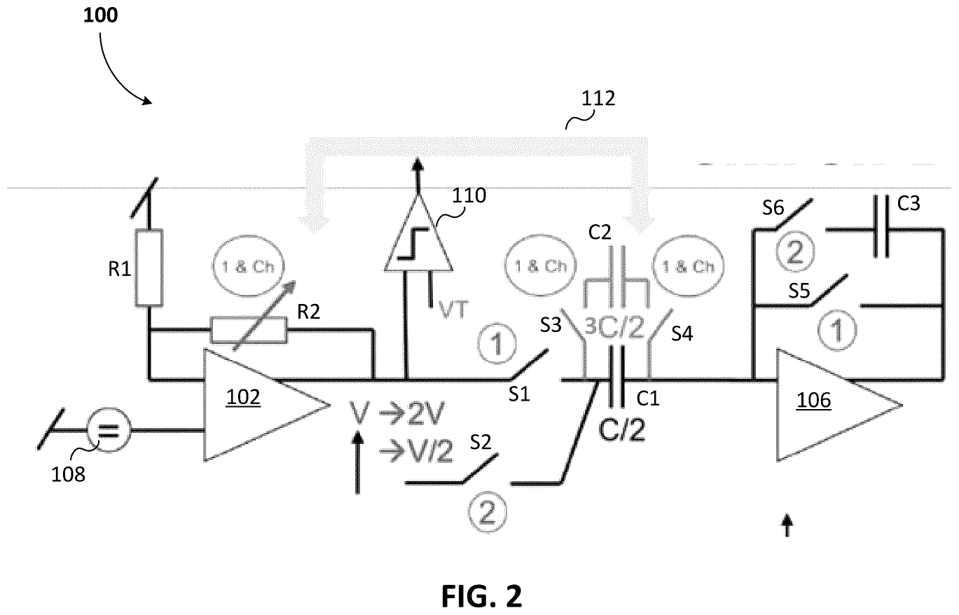

FIG. 2 is a high-level schematic of a microphone circuit 100, according to an implementation of the embodiment of FIG. 1A. Microphone circuit 100 comprises a MEMS device 108 for providing an analog signal, and a programmable gain amplifier including an operational amplifier 102 having a first input coupled to MEMS device 108, a second input coupled to the junction between a first end of resistor R1 and a first end of adjustable resistor R2. A second end of resistor R1 is coupled to ground. A second end of resistor R2 is coupled to an output of operational amplifier 102. Microphone circuit also comprises an integrator from an SD ADC, including switches S1, S2, S3, S4, S5, and S6, capacitors C1, C2, and C3, and amplifier 106. The value of capacitor C3 is used to scale the integrator output voltage. Microphone circuit 100 further comprises a comparator 110 having a first input coupled to the output of operational amplifier 102, and a second input for receiving a VT threshold voltage. An output of comparator provides control signals 112 for changing the value of adjustable resistor R2, as well as the state of switches S1 and S2 to adjust the capacitor value of the integrator. The programmable gain amplifier in FIG. 2 is a resistive feedback amplifier, which may benefit from calibration to match gains with the integrator (which uses uncorrelated capacitor gain components).

Microphone circuit 100 operates in two phases. A first phase is a sampling phase in which switches S1 and S5 are closed, and switches S2 and S6 are open. In the first phase capacitor C1 or the combination of capacitors C1 and C2 are charged to the voltage at the PGA. A second phase mode of operation is an integration phase in which switches S1 and S5 are open, and switches S2 and S6 are closed. Switch S2 is also coupled to ground or a reference voltage source. In the second phase, the sampled voltage is integrated in the integrator.

The PGA gain is reduced and the integrator gain is increased when the voltage at the output of operational amplifier 102 exceeds ±VT. Capacitor C2 is switched in parallel in phase “1 & ch” to diminish glitches (the first sampling mode and also gain change during the first sampling mode). For small signals sigma-delta ADC including the integrator shown in FIG. 2 is still is single-bit with good kT/C SNR. In some embodiments, comparator 110 can be replaced with a flash ADC instead. In FIG. 2 a PGA output voltage of “V” and an integrator input capacitance value of “C” provides an “original” value of SNR (not shown in FIG. 2), wherein “V” is a nominal voltage value and “C” is a nominal capacitance value. For small analog input signals, a PGA output voltage “2V” and an integrator input capacitance of “C/2” provides an increased value of SNR+3 dB. For large analog input signals, a PGA output voltage of “V/2” and an integrator input capacitance of “2C” provides a decreased value of SNR −3 dB, wherein “2C” is the total parallel capacitance of capacitors C1 and C2. While only two gain modes are thus actually shown in FIG. 2, those skilled in the art will realize that additional gain modes can be provided with additional voltage and capacitor values, and graph curves to accommodate these additional gain modes.

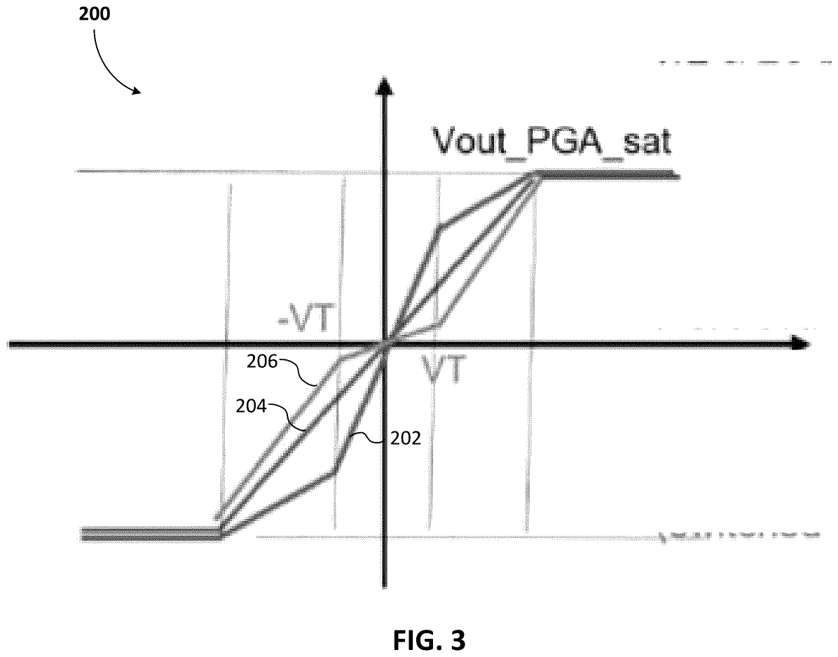

FIG. 3 is a plot of the gain characteristics of the circuit of FIG. 2 in various gain modes, according to an implementation. The trace 206 is the SD ADC transfer function, and the trace 202 is the PGA transfer function, and can be switched depending upon the input signal level. The trace 204 is the “original” nominal gain value. As previously explained, the number of graph curves is related to the number of gain modes that are used. There are two gain modes with a comparator for the gain change component, and an arbitrary number of gains with an ADC as the gain change component.

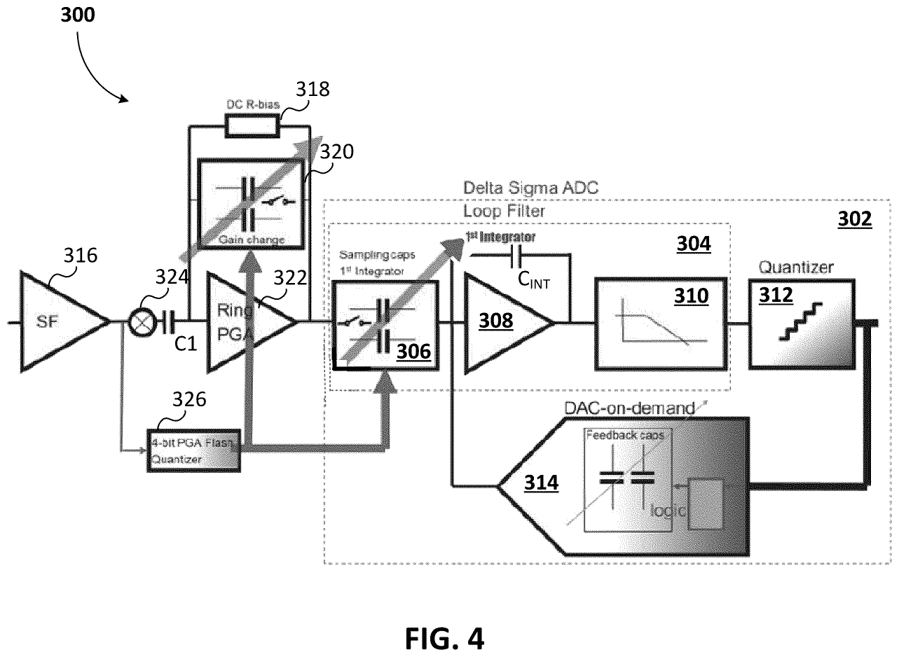

FIG. 4 is a schematic diagram of a circuit 300 including a PGA and an ADC, as well as gain adjustment features according to an implementation. In particular, circuit 300 includes a source follower 316 (or amplifier implemented as a source follower) for receiving an analog signal, and a chopper 324 coupled to an output of source follower 316. In some embodiments source follower 316 can comprise an amplifier configured as a source follower, an attenuator, or a low gain amplifier. A programmable amplifier comprises a PGA 322 (implemented as a ring PGA or any suitable amplifier), an input capacitor C1, an array of selectable gain change capacitors 320 in a feedback arrangement, and DC bias resistor 318 also in a feedback arrangement around PGA 322. Circuit 300 further comprises a SD ADC 302 including a loop filter 304. The loop filter 304 comprises an integrator including a set of selectable sampling capacitors 306, an amplifier 308, and a constant value integration capacitor CINT in a feedback configuration around amplifier 308. The loop filter also includes a low pass filter 310 coupled to the output of the integrator. Loop filter 304 is coupled to a multi-level quantizer 312 to provide a digital output for circuit 300. Finally, a DAC-on-demand 314 is coupled to the digital output to return an analog voltage to the integrator. DAC-on-demand 314 includes a logic circuit and a set of selectable feedback capacitors, wherein at least one feedback capacitor is selected. Further feedback capacitors are selected depending upon the quantizer output. The structure and operation of the DAC-on-demand 314 is further explained in U.S. Pat. No. 11,863,196 entitled “Microphones with an On-Demand Digital-to-Analog Converter”, which is hereby incorporated by reference.

In the embodiment of FIG. 4, there is only one chopper 324 interposed between the output of source follower 316 and the input of PGA 322. A dedicated four-bit flash quantizer 326 controls the selection of the sampling caps array in the SD ADC 302 and the array of selectable gain change capacitors 320 in the PGA. The charge gain is kept constant (Q=CV) but with an increased SNR for small signals. Further, as previously stated PGA 322 can comprise any suitable amplifier. It is also important to note that in FIG. 4 the two arrows associated with the array of selectable gain change capacitors 320 and selectable sampling capacitors 306 point in the same direction. However, they indicate the inverse gain relationship between the programmable gain amplifier (feedback gain capacitors) and SD ADC 302 (input gain change capacitors).

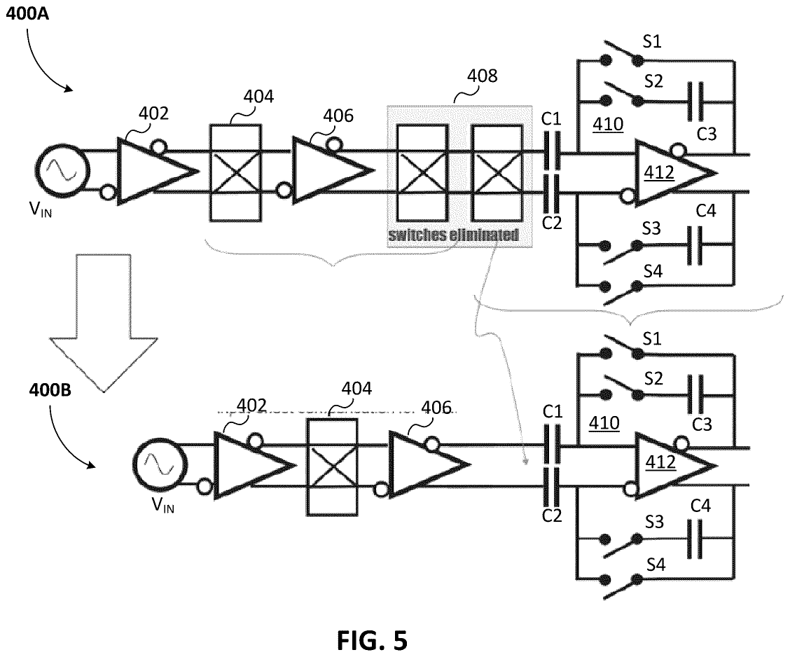

FIG. 5 is a schematic diagram of a circuit including a PGA and an ADC, as well as gain adjustment features according to an implementation. Circuit 400A includes, in series, a VIN voltage source, a first differential amplifier 402, a first chopper 404, a second differential amplifier 406, a set 408 of two serially-coupled choppers, and an integrator comprising input capacitors C1 and C2, amplifier 412, switches S1, S2, S3, S4, and integration capacitors C3 and C4. The first chopper 404 and the first chopper in set 408 are paired together for chopper stabilization and elimination of DC offset. The second chopper in set 408 is used in the integrator as cross-coupled sampling switches. In embodiments, chopper stabilization is employed to perform auto-zero functions to eliminate voltage offsets and reduce flicker noise.

In circuit 400B, the inventors have recognized that both choppers in set 408 can be eliminated from the circuit since they functionally cancel each other out, which advantageously saves power and circuit area. Proper operation of the integrator is supplied at the input by first chopper 404. In the implementation of circuit 400B, at least the second differential amplifier 406 comprises two fixed value input capacitors and two variable feedback capacitors, and capacitors C1 and C2 comprise variable capacitors. In an embodiment, the second differential amplifier 406 can comprise the combination of capacitor C1, PGA 322, gain change capacitors 320, and DC bias resistor 318 as shown in FIG. 4.

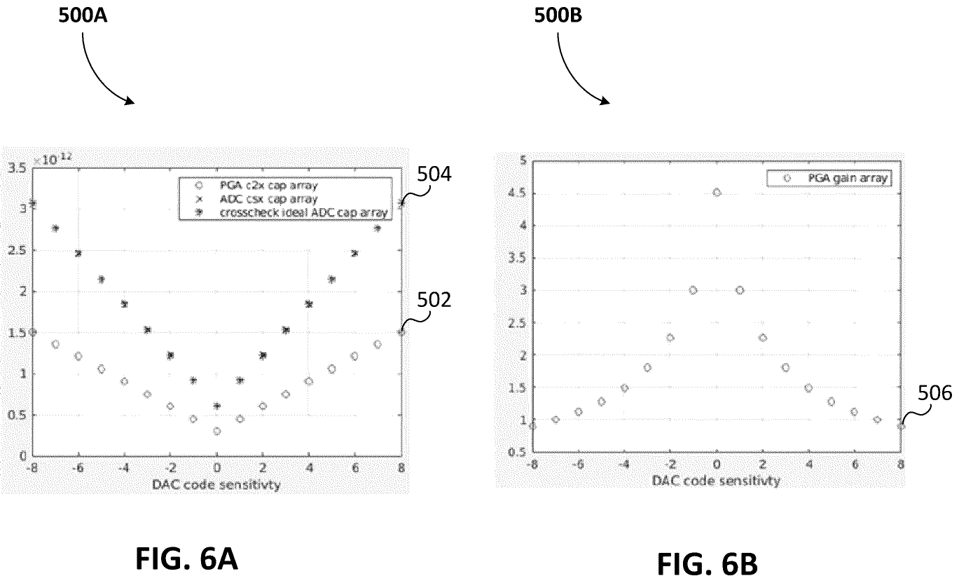

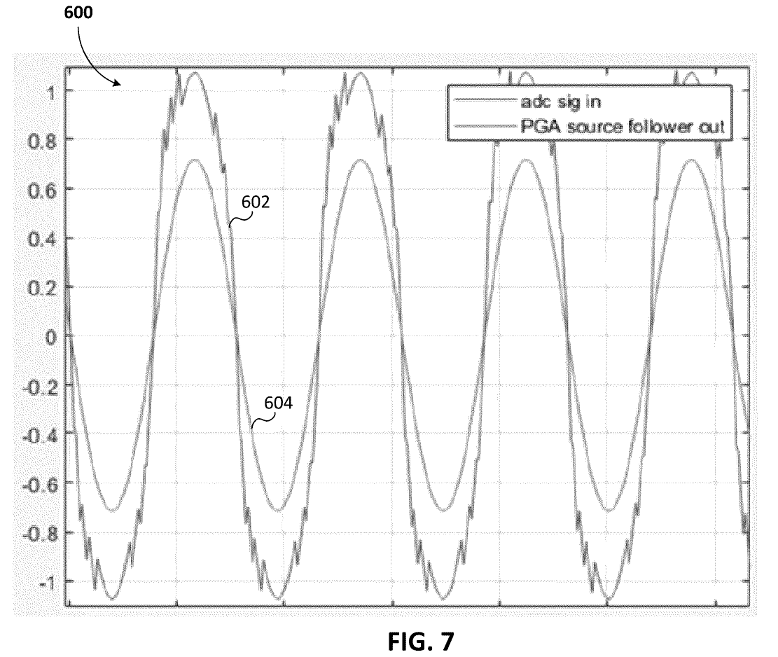

FIG. 6A is a plot 500A of the PGA capacitor array values in picofarads (pF) and ADC capacitor array values according to an embodiment; and FIG. 6B is a plot 500B of PGA gain array values, according to an embodiment. Trace 504 shows an example of the change in the sampling capacitors for the integrator and trace 502 shows an example of the change in the feedback capacitors of the PGA, with respect to the DAC code sensitivity. In FIG. 6A the X-axis represents the number of capacitor cells used, and the Y-axis represents the total capacitor value that is used. The nonlinear gain of the PGA (~1/x) is depicted in trace 506 of FIG. 6B. Other linear and nonlinear combinations are possible, as well as uniform and non-uniform combinations. For example, although the ratio of capacitors remains the same (“constant charge”), the way in which the jump from code to code is implemented can be nonlinear in an embodiment. Other threshold levels for the switching of the capacitors for the PGA and integrator and/or the number of switching levels are also possible. Resistive gains in the PGA and the ADC can also be used, except that the auto-zero feature discussed above is replaced by other chopping techniques.

FIG. 7 is a plot 600 of the ADC input signal 602 and a source follower output signal 604, according to an embodiment. Note that while the source follower output signal 604 is a “clean” version of the analog input signal, the ADC input signal has switching artifacts introduced by the sole chopper and by the change of gain setting, which are filtered out by the action of the integrator. The synchronous change of the integrator sampling capacitors and the PGA feedback capacitors enables a constant charge transfer without “jumping” artifacts (except for the intrinsic mismatch between the gain capacitors of the PGA and the sampling capacitors of the ADC~10 bits accuracy, and due to related settling gain changes~10 bits=60 dB OPAMP gain).

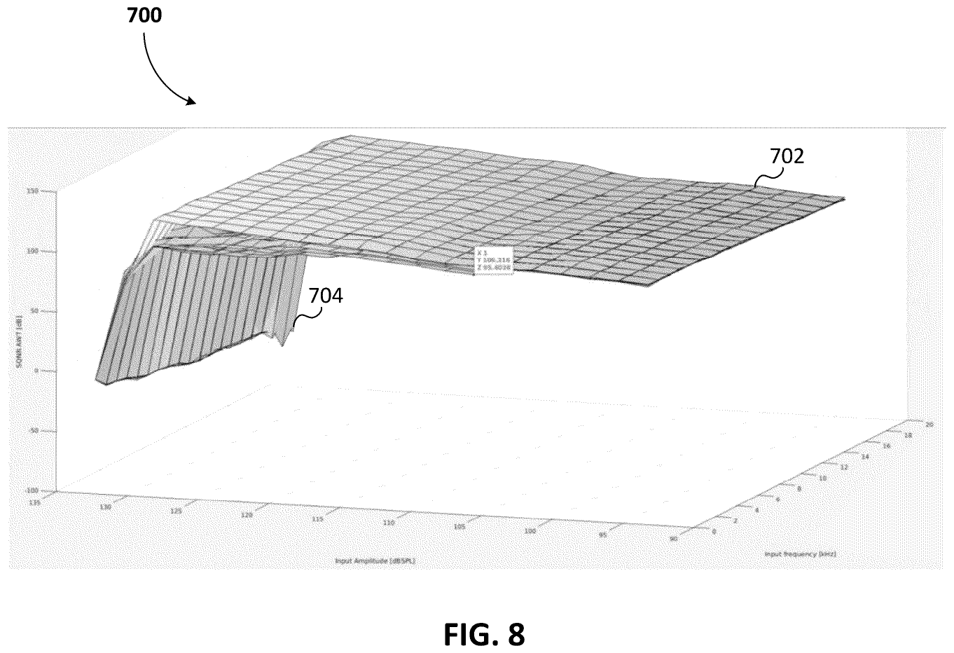

FIG. 8 is a 3D plot of the “A-Weighted” Signal-to-Quantization-Noise Ratio (SQNR), (surface 704) in decibels versus input audio frequency (both input amplitude and input frequency) using Monte Carlo (MC) analysis. FIG. 8 shows the Signal to Quantization Noise Ratio (SQNR) for the ideal case 702 versus the MC mismatch induced degradation, (surface 704). The SNR of the entire signal path as shown in FIG. 4 (thermal included) is lower and less sensitive to mismatch. The DAC-on-demand features assure the full SNR improvements (as it makes the K/TC noise of the reference path neglibible for small signals).

Example embodiments of the present invention are summarized here. Other embodiments can also be understood from the entirety of the specification and the claims filed herein.

Example 1. According to an embodiment, a circuit comprises a programmable gain amplifier configured to receive an analog input signal; an integrator having an input coupled to an output of the programmable gain amplifier; and a gain change component configured to monitor the analog input signal, and configured to change a gain of the programmable gain amplifier and a gain of the integrator based on the monitored analog input signal, wherein a gain change of the programmable gain amplifier is inversely related to a gain change of the integrator.

Example 2. The circuit of Example 1, further comprising a chopper in series with an input of the programmable gain amplifier, wherein the chopper is configured to reverse a polarity of the analog input signal during a sampling interval of the circuit.

Example 3. The circuit of any of the above examples, wherein the integrator comprises a switched capacitor integrator as a first stage of a sigma-delta analog-to-digital converter (ADC).

Example 4. The circuit of any of the above examples, wherein the integrator comprises adjustable input coupling capacitors, and wherein the programmable gain amplifier comprises a switched-capacitor programmable gain amplifier having adjustable feedback capacitors.

Example 5. The circuit of any of the above examples, wherein the output of the programmable gain amplifier is operatively coupled to an input of the integrator without an interposing phase switch or chopper.

Example 6. The circuit of any of the above examples, wherein the gain change component comprises a comparator, an additional ADC, a digital circuit, or provided as an external signal, and where at least one input of the gain change component is coupled to an input of the circuit, an output of the circuit, or an output of the programmable gain amplifier.

Example 7. According to an embodiment, a method comprises receiving an analog input signal at an input of a programmable gain amplifier and amplifying, by the programmable gain amplifier, analog signal to form an amplified signal; integrating, by an integrator having an input coupled to an output of the programmable gain amplifier, the amplified signal; monitoring the analog input signal; and changing a gain of the programmable gain amplifier and a gain of the integrator based on the monitored analog input signal, wherein a gain change of the programmable gain amplifier is inversely related to a gain change of the integrator.

Example 8. The method of Example 7, further comprising chopping, by a chopper, the analog input signal by reversing a polarity of the analog input signal during a sampling interval to form a chopped signal.

Example 9. The method of any of the above examples, further comprising operatively coupling an output of the programmable gain amplifier to the input of the integrator without an interposing phase switch or chopper.

Example 10. The method of any of the above examples, wherein the integrator comprises a switched capacitor integrator as a first stage of a sigma-delta analog-to-digital converter (ADC).

Example 11. The method of any of the above examples, further comprising adjusting input coupling capacitors of the integrator, and further comprising adjusting feedback capacitors of the programmable gain amplifier.

Example 12. The method of any of the above examples, further comprising calibrating the gain of the programmable gain amplifier and the gain of the integrator to improve mismatch performance.

Example 13. According to an embodiment, a circuit comprises a circuit input for receiving an analog signal; a first amplifier having an input coupled to the circuit input; a second amplifier having an input coupled to an output of the first amplifier; an analog-to-digital converter (ADC) having an input coupled to an output of the second amplifier and output coupled to a circuit output; and a gain change component configured for monitoring the analog signal, the gain change component coupled to a gain change input of the second amplifier, and to a gain change input of an integrator in the ADC, wherein a gain change of the second amplifier is inversely related to a gain change of the integrator.

Example 14. The circuit of Example 13, further comprising a chopper interposed between the first amplifier and the second amplifier.

Example 15. The circuit of any of the above examples, wherein the output of the second amplifier is coupled to an input of the ADC without an interposing phase switch or chopper.

Example 16. The circuit of any of the above examples, wherein the first amplifier comprises a source follower, an attenuator, or a low gain amplifier.

Example 17. The circuit of any of the above examples, wherein the second amplifier comprises a switched-capacitor programmable gain amplifier having adjustable feedback capacitors, or a resistive feedback amplifier.

Example 18. The circuit of any of the above examples, wherein the gain change component comprises a comparator, a flash quantizer, an additional ADC, a digital circuit, or provided as an external signal, and where at least one input of the gain change component is coupled to an input of the circuit, an output of the circuit, or the output of the first amplifier.

Example 19. The circuit of any of the above examples, wherein the integrator comprises a plurality of selectable input capacitors, and comprises a first stage of a sigma-delta ADC.

Example 20. The circuit of any of the above examples, wherein the ADC comprises a digital-to-analog converter (DAC) comprising a plurality of selectable capacitors, and wherein the DAC comprises an on-demand DAC.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A circuit comprising:
a programmable gain amplifier configured to receive an analog input signal;
an integrator having an input coupled to an output of the programmable gain amplifier; and
a gain change component configured to monitor the analog input signal, and configured to change a gain of the programmable gain amplifier and a gain of the integrator based on the monitored analog input signal, wherein a gain change of the programmable gain amplifier is inversely related to a gain change of the integrator.

2. The circuit of claim 1, further comprising a chopper in series with an input of the programmable gain amplifier, wherein the chopper is configured to reverse a polarity of the analog input signal during a sampling interval of the circuit.

3. The circuit of claim 1, wherein the integrator comprises a switched capacitor integrator as a first stage of a sigma-delta analog-to-digital converter (ADC).

4. The circuit of claim 3, wherein the integrator comprises adjustable input coupling capacitors, and wherein the programmable gain amplifier comprises a switched-capacitor programmable gain amplifier having adjustable feedback capacitors.

5. The circuit of claim 1, wherein the output of the programmable gain amplifier is operatively coupled to an input of the integrator without an interposing phase switch or chopper.

6. The circuit of claim 1, wherein the gain change component comprises a comparator, an additional ADC, a digital circuit, or provided as an external signal, and where at least one input of the gain change component is coupled to an input of the circuit, an output of the circuit, or an output of the programmable gain amplifier.

7. A method comprising:
receiving an analog input signal at an input of a programmable gain amplifier and amplifying, by the programmable gain amplifier, analog signal to form an amplified signal;
integrating, by an integrator having an input coupled to an output of the programmable gain amplifier, the amplified signal;
monitoring the analog input signal; and
changing a gain of the programmable gain amplifier and a gain of the integrator based on the monitored analog input signal, wherein a gain change of the programmable gain amplifier is inversely related to a gain change of the integrator.

8. The method of claim 7, further comprising chopping, by a chopper, the analog input signal by reversing a polarity of the analog input signal during a sampling interval to form a chopped signal.

9. The method of claim 7, further comprising operatively coupling an output of the programmable gain amplifier to the input of the integrator without an interposing phase switch or chopper.

10. The method of claim 7, wherein the integrator comprises a switched capacitor integrator as a first stage of a sigma-delta analog-to-digital converter (ADC).

11. The method of claim 7, further comprising adjusting input coupling capacitors of the integrator, and further comprising adjusting feedback capacitors of the programmable gain amplifier.

12. The method of claim 7, further comprising calibrating the gain of the programmable gain amplifier and the gain of the integrator to improve mismatch performance.

13. A circuit comprising:
a circuit input for receiving an analog signal;
a first amplifier having an input coupled to the circuit input;
a second amplifier having an input coupled to an output of the first amplifier;
an analog-to-digital converter (ADC) having an input coupled to an output of the second amplifier and output coupled to a circuit output; and
a gain change component configured for monitoring the analog signal, the gain change component coupled to a gain change input of the second amplifier, and to a gain change input of an integrator in the ADC, wherein a gain change of the second amplifier is inversely related to a gain change of the integrator.

14. The circuit of claim 13, further comprising a chopper interposed between the first amplifier and the second amplifier.

15. The circuit of claim 13, wherein the output of the second amplifier is coupled to an input of the ADC without an interposing phase switch or chopper.

16. The circuit of claim 13, wherein the first amplifier comprises a source follower, an attenuator, or a low gain amplifier.

17. The circuit of claim 13, wherein the second amplifier comprises a switched-capacitor programmable gain amplifier having adjustable feedback capacitors, or a resistive feedback amplifier.

18. The circuit of claim 13, wherein the gain change component comprises a comparator, a flash quantizer, an additional ADC, a digital circuit, or provided as an external signal, and where at least one input of the gain change component is coupled to an input of the circuit, an output of the circuit, or the output of the first amplifier.

19. The circuit of claim 13, wherein the integrator comprises a plurality of selectable input capacitors, and comprises a first stage of a sigma-delta ADC.

20. The circuit of claim 13, wherein the ADC comprises a digital-to-analog converter (DAC) comprising a plurality of selectable capacitors, and wherein the DAC comprises an on-demand DAC.
